(19) United States
(12) Patent Application Publication
(10) Pub. No.: US 2025/0087542 A1
(43) Pub. Date: Mar. 13, 2025

(54) Package Substrates with Corner Stiffeners Extensions

(71) Applicant: Intel Corporation, Santa Clara, CA (US)

(72) Inventors: Man Chun OOH, Menglembu (MY); Wei Chung LEE, Nibong Tebal (MY); Yean Ling SOON, Butterworth (MY); Kor Oon LEE, Simpang Ampat (MY); Jackson Chung Peng KONG, Tanjung Tokong (MY); Azniza ABD AZIZ, Perai (MY); Piyush BHATT, Bengaluru (IN)

(21) Appl. No.: 18/466,019

(22) Filed: Sep. 13, 2023

(51) Int. Cl. H01L 23/24; H01L 23/498

(52) U.S. Cl. CPC H01L 23/24; H01L 23/49816; H01L 23/49838

(57) ABSTRACT

The present disclosure is directed to an improved stiffener that has a body that has extension members positioned proximally to the corners of a semiconductor package substrate, and the extension members have bottom extension surfaces that extend beyond a periphery of a bottom surface of the semiconductor package substrate, and the bottom extension surfaces and the bottom surface of the semiconductor package substrate are co-planar. The present disclosure is also directed to a method for forming the improved stiffener with the extension members for a semiconductor package.

### BACKGROUND

For integrated circuit design and fabrication, the need to improve performance and lower costs are constant challenges. The high-volume manufacturing (HVM) of semiconductor packages may produce yield losses caused by package warpage during the assembly process. Package warpage may be the result of multiple factors such as coefficient of thermal expansion (CTE) mismatches, the stack-up of different types of components, and the various thermal processing steps that the semiconductor packages undergo during the assembly process.

A commonly used approach to controlling warpage uses a mechanical part, such as a stiffener, to improve the strength of package substrates and/or printed circuit boards (PCB) and minimize the warpage. The stiffener enhances the durability of the package substrate and PCB by adding thickness and reinforcing, for example, the areas in which components will be mounted.

Presently, HVM processes provide the semiconductor packages with glue at the package corners to hold the packages in place and prevent warp. However, the placement of glue at the corners of the package may result in the glue infiltrating into the package's signal ball grid array (BGA) layer, thereby degrading the signal integrity performance of the BGA. To prevent such degradation, it may be necessary to move the signals away from the package edge, which, in turn, may increase the routing congestion and reduce signal integrity performance due to crosstalk. A solution used in place of glue requires adding rows of BGAs at the edges of the package, which may increase the package's size and cost.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show exemplary representations of a semiconductor package with a stiffener according to an aspect of the present disclosure;

FIGS. 2 and 2A show exemplary representations of a stiffener according to another aspect of the present disclosure;

FIG. 3 shows an exemplary representation of the formation of a stiffener according to an aspect of the present disclosure;

FIGS. 4A through 4D and FIGS. 4A′ through 4D′ show exemplary representations of a method of making a semiconductor package with a stiffener according to an aspect of the present disclosure;

FIGS. 5A and 5B show exemplary perspective views of two semiconductor packages with stiffeners according to aspects of the present disclosure;

FIGS. 6A and 6B show exemplary representations of solder ball grid arrays for two semiconductor packages with stiffeners according to aspects of the present disclosure;

FIG. 7 shows an exemplary perspective view of a semiconductor package with a stiffener according to another aspect of the present disclosure; and

FIG. 8 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present stiffeners are designed to replace the commonly used stiffener and package corner glue. For example, a present “zig-zag” corner stiffener for a semiconductor package may reduce corner solder joint reliability risk and prevent electrical signal degradation from the use of package corner glue, which can cause impedance discontinuity, return and insertion loss in high-speed input/output (HSIO) signals due to glue penetration. Furthermore, the present stiffener design may allow package size and platform design length to be maintained or possibly reduced since the aforementioned potential losses from the use of the package corner glue may be avoided.

In a further aspect, the present stiffeners have extension members located near the corners of the package substrate. The package substrate has a bottom surface that is provided with a solder ball grid array for coupling/attachment with a printed circuit board (PCB). The extension member may have a zig-zag shape, and the zig-zag shape includes a bottom extension surface that provides additional surface area extending from the bottom surface of the package substrate to place additional solder balls.

The present disclosure provides an improved stiffener that has a body that is a component of a semiconductor device package for providing rigidity. In an aspect, the body has extension members positioned proximally to corners of the semiconductor package substrate, and the extension members comprise bottom extension surfaces that extend beyond a periphery of a bottom surface of the semiconductor package substrate, and the bottom extension surfaces and the bottom surface of the semiconductor package substrate are co-planar.

The present disclosure is also directed to a method that includes forming a stiffener having a frame with extension members that protrude from the frame, providing a device platform with a top surface and a bottom surface for forming a semiconductor package, disposing at least one semiconductor device onto the top surface of the device platform, disposing the frame of the stiffener onto the top surface of the device platform, and each of the extension members of the stiffener includes a bottom extension surface that is positioned proximal to a corner of the device platform and provides an extension to the bottom surface of the device platform.

The present disclosure is further directed to a semiconductor package including a package substrate having a top surface and a bottom surface that provide a periphery and corners, a stiffener comprising a rigid body with extension members, for which the rigid body is disposed on the top surface of the package substrate and extension members are positioned proximally to the corners of the package substrate, the extension members comprise bottom extension surfaces that extend beyond the periphery of the package substrate, and a semiconductor device disposed on the top surface of the package substrate.

The technical advantages of the present disclosure include, but are not limited to:
(i) providing an improved stiffener that provides greater package substrate corner solder joint reliability and warpage control:
(ii) providing an alternative to the use of package substrate corner glue and eliminating the problem of glue penetration into a solder ball grid array for the package substrate, as well as the remedial steps needed to address the glue penetration; and
(iii) allowing for improved signal integrity, as well as the use of the edge and corner portions of the package substrate for signal and other routing lines.

To more readily understand and put into practical effect the present stiffener and semiconductor package structures and methods for their fabrication, which may be used for improving warpage control and signal integrity, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

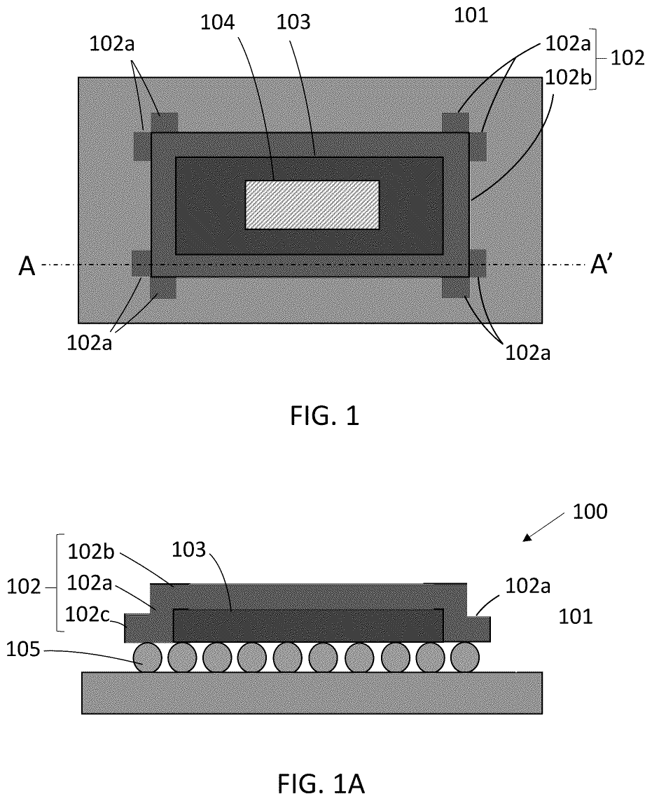

FIGS. 1 and 1A show exemplary representations of a semiconductor package 100 with a stiffener 102 with extension members 102a according to an aspect of the present disclosure. The FIG. 1A is a cross-sectional view along the section line A-A′ shown in FIG. 1. The semiconductor package 100 may include a package substrate/device platform 103 and a die 104. The stiffener 102 may have a frame or rigid body 102b and the extension members 102a may protrude or extend from the frame 102b for positioning proximally to corners of a semiconductor package substrate. The stiffener 102 provides rigidity for the semiconductor package 100. The extension members 102a may have a zig-zag shape as shown, but it is within the scope of the present disclosure to have the extension members be formed in other shapes, e.g., an arc shape, triangular shape, or other shape.

In an aspect, as shown in FIG. 1A, the frame 102b may be positioned on an upper surface of the package substrate 103, and the extension members 102a include a bottom extension surface 102c, which may be co-planar with a bottom surface of the package substrate. The bottom extension surface 102c and the bottom surface of the package substrate may be provided with solder balls 105 for coupling/attachment with a printed circuit board 101.

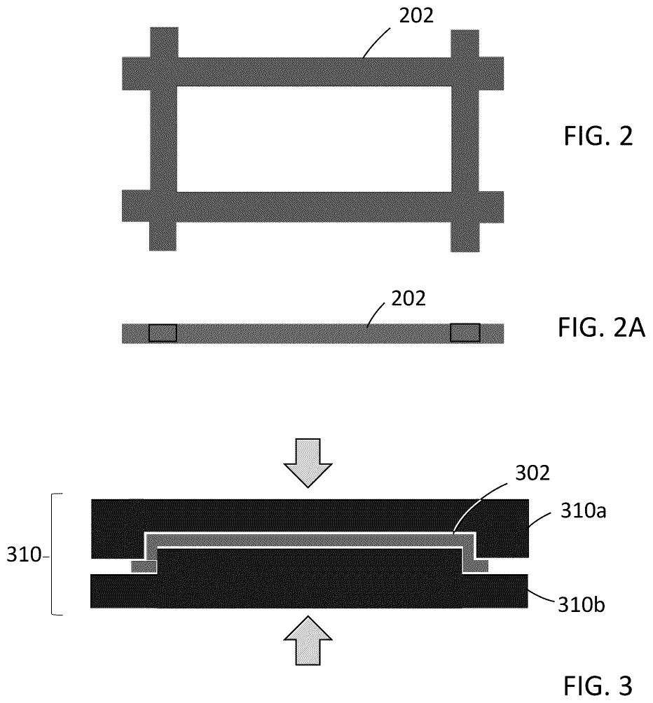

FIGS. 2 and 2A show exemplary representations of a stiffener 202 as a pre-form template according to another aspect of the present disclosure. FIG. 2A is a side view of the pre-form stiffener template 202. In general, the stiffener 202 can be made of a material that has a higher elastic modulus than the elastic modulus of a package substrate. For example, the stiffener 202 can be made of a metal (e.g., aluminum, copper, or steel), a ceramic, a composite material, or another appropriate material (e.g., a ceramic material). The stiffener 202 may be a single unitary structure or composed of multiple “subunit” structures that are assembled or coupled to one another (not shown). The unitary structure may be made, for example, using a stamp press as shown in FIG. 3.

FIG. 3 shows an exemplary representation of the formation of a present stiffener 302 according to an aspect of the present disclosure. A pre-form stiffener template 202, as shown in FIG. 2A, may be placed in a press machine 310 having a top unit 310a and a bottom unit 310b. The stiffener 302 may be formed by applying pressure to the pre-form stiffener template using the top unit 310a and the bottom unit 310b as shown.

It should be understood that the present stiffener may be formed using a variety of methods including injection molding, 3D printing, etc. The selection of the manufacturing method and stiffener material may be determined by the selected shape of the extension members of a present stiffener.

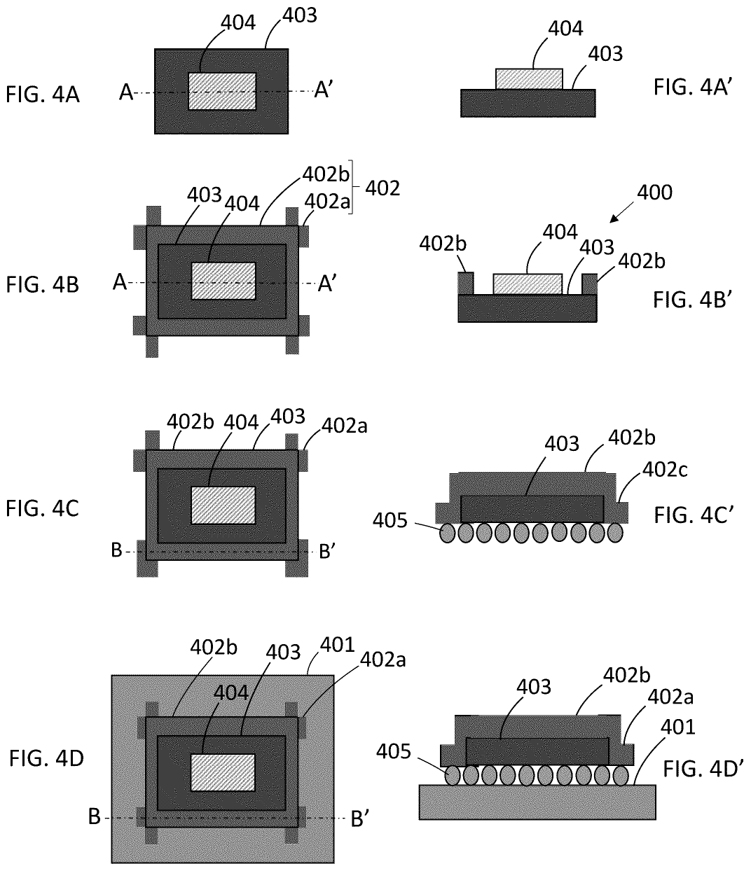

FIGS. 4A through 4D and FIGS. 4A′ through 4D′ show exemplary representations of a method for making a semiconductor package 400 with a stiffener according to an aspect of the present disclosure. In FIGS. 4 and 4A′, a semiconductor die 404 disposed on a package substrate 403 is shown. FIG. 4A′ is a cross-sectional view along a section line A-A′ shown in FIG. 4A. In FIGS. 4B and 4B′, a stiffener 402 having a frame 402b, extension member 402a and bottom extensions 402c may be disposed on the package substrate 403 as part of a semiconductor package 400. FIG. 4B′ is a cross-sectional view along a section line A-A′ shown in FIG. 4B. It should be understood that it is within the scope of the present method to place a present stiffener on a package substrate before a semiconductor die is placed on the package substrate.

According to further steps in the method, as shown in FIG. 4C′, a solder ball grid array 405 may be placed on a bottom surface of the package substrate 403 and the bottom extension surfaces 402c. FIG. 4C′ is a cross-sectional view along a section line B-B′ shown in FIG. 4C. In FIGS. 4D and 4D′, the semiconductor package 400 may be coupled to a printed circuit board 401, for example, using a surface mounting technology. FIG. 4D′ is a cross-sectional view along a section line B-B′ shown in FIG. 4D.

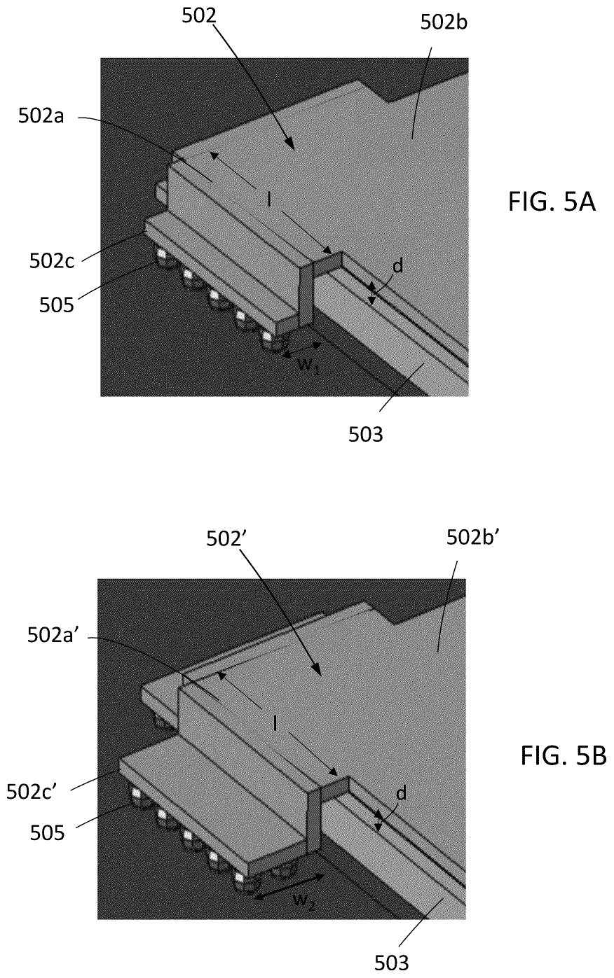

FIGS. 5A and 5B show exemplary partial perspective views of two semiconductor packages with stiffeners according to aspects of the present disclosure. In an aspect shown in FIG. 5A, a stiffener 502 may be positioned on a package substrate 503. The stiffener 502 may have extension members 502a that extend from a frame 502b and a thickness d. As shown in FIGS. 5A, the frame 502b may be spaced apart from the edges of the package substrate 503. The extension members 502a may have bottom extension surfaces 502c and have a length l. The bottom extension surface 502c may have a width w₁ that can accommodate one row of solder balls 505. In this aspect, for example, the stiffener 502 may have a thickness d that may be approximately 0.25 mm, the extension member 502a may have a length l that may be approximately 3.25 mm, and the bottom extension surface 502c may have a width w₁ that may be approximately 0.91 mm.

In another aspect shown in FIG. 5B, a stiffener 502′ may be positioned on a package substrate 503. The stiffener 502′ may have extension members 502a′ that extend from a frame 502b′ and a thickness d. As shown in FIG. 5B, the frame 502b′ may be spaced apart from the edges of the package substrate 503. The extension members 502a′ may have bottom extension surfaces 502c′ and have a length l. The bottom extension surface 502c′ may have a width w₂ that can accommodate two rows of solder balls 505. In this aspect, for example, the stiffener 502′ may have a thickness d that may be approximately 0.25 mm, the extension member 502a′ may have a length l that may be approximately 3.25 mm, and the bottom extension surface 502c′ may have a width w₂ that may be approximately 1.56 mm.

It should be understood that the shape and size of a particular stiffener, including values for l, w₁, w₂, and d, may be designed to accommodate the shape and size of a package substrate, as well as the routing lines on both the package substrate and a printed circuit board that the stiffener will be thereon attached.

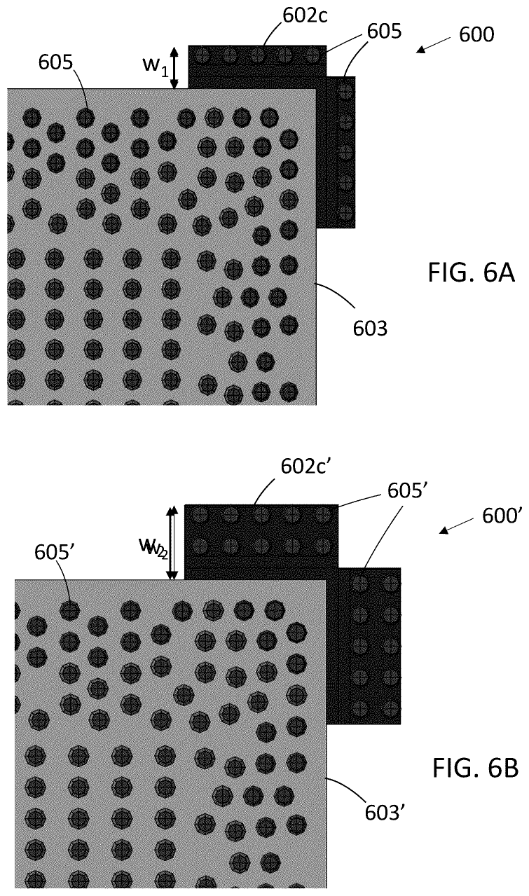

FIGS. 6A and 6B show exemplary representations of solder ball grid arrays for two semiconductor packages with stiffeners according to aspects of the present disclosure. In FIG. 6A, a partial bottom side view of semiconductor package 600 that provides a bottom surface of a package substrate 603 with bottom extension surfaces 602c, which have a width w₁. The bottom surface of the package substrate 603 with bottom extension surfaces 602c may have a plurality of solder balls 605 disposed thereon. The width w₁ of the bottom extension surfaces 602c may accommodate one row of solder balls 605.

In FIG. 6B, a partial bottom side view of the semiconductor package 600′ that provides a bottom surface of a package substrate 603′ with bottom extension surfaces 602c′, which have a width w₂. The bottom surface of the package substrate 603′ and the bottom extension surfaces 602c′ have a plurality of solder balls 605′. The width w₂ of the bottom extension surfaces 602c may accommodate two rows of solder balls 605.

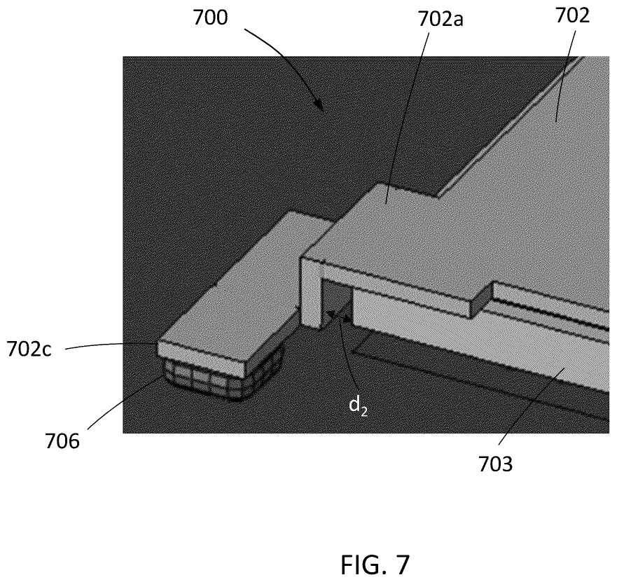

FIG. 7 shows an exemplary partial perspective view of a semiconductor package 700 with a stiffener 702 according to another aspect of the present disclosure. In this aspect, the stiffener 702 may have extension members 702a that extend the bottom extension surfaces 702c by a distance d₂ from corners of a package substrate 703. In addition, a solder patch 706 may be used in place of solder balls for attachment of bottom extension surfaces to a printed circuit board (not shown). This configuration may be used to accommodate routing lines in a print circuit board connecting to a semiconductor package.

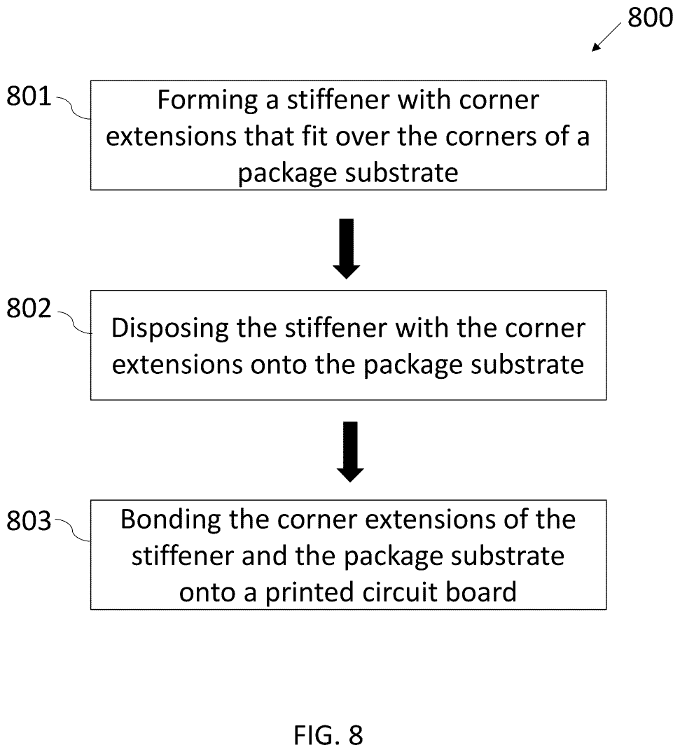

FIG. 8 shows a simplified flow diagram for an exemplary method 800 according to an aspect of the present disclosure.

The operation 801 may be directed to forming a stiffener with corner extensions that fit over the corners of a package substrate. The corner extensions may have a zig-zag shape and bottom extension surfaces that are co-planar with a bottom surface of the package substrate.

The operation 802 may be directed to disposing the stiffener with the corner extensions onto the package substrate. The bottom extension surfaces of the corner extensions are co-planar with a bottom surface of the package substrate.

The operation 803 may be directed to bonding the corner extensions of the stiffener and the package substrate onto a printed circuit board. The bottom extension surfaces of the corner extensions and the bottom surface of the package substrate are provided with a solder ball grid array and the semiconductor package is surface mounted to the printed circuit board.

It will be understood that any property described herein for a particular stiffener or package structure and a method for their fabrication may also hold for any electronic component using the present stiffener and semiconductor package described herein. It will also be understood that any property described herein for a specific method may hold for any of the methods described herein. Furthermore, it will be understood that for any present stiffener and package structure and the methods described herein, not necessarily all the components or operations described will be shown in the accompanying drawings or method, but only some (not all) components or operations may be disclosed.

To more readily understand and put into practical effect the present stiffener and semiconductor package structure, they will now be described by way of examples. For the sake of brevity, duplicate descriptions of features and properties may be omitted.

### Examples

Example 1 provides a device including a body having extension members for positioning proximally to corners of a semiconductor package substrate, for which the body is a component of a semiconductor device package for providing rigidity, and the extension members having bottom extension surfaces that extend beyond a periphery of a bottom surface of the semiconductor package substrate, for which the bottom extension surfaces and the bottom surface of the semiconductor package substrate are co-planar.

Example 2 may include the device of example 1 and/or any other example disclosed herein, for which the body includes a frame that is positioned along a periphery of an upper surface of the semiconductor package substrate.

Example 3 may include the device of example 1 and/or any other example disclosed herein, for which the bottom extension surfaces have a width to accommodate at least one row of solder balls that are positioned beyond the periphery of the semiconductor package substrate.

Example 4 may include the device of example 2 and/or any other example disclosed herein, for which the frame includes a unitary structure or an assembled structure.

Example 5 may include the device of example 1 and/or any other example disclosed herein, for which the body includes a metallic material.

Example 6 may include the device of example 1 and/or any other example disclosed herein, for which the body includes a ceramic material.

Example 7 may include the device of example 1 and/or any other example disclosed herein, for which the bottom extension surfaces are formed to be in close proximity to the bottom surface of the semiconductor package substrate.

Example 8 may include the device of example 1 and/or any other example disclosed herein, for which the bottom extension surfaces are formed to be spaced apart from the bottom surface of the semiconductor package substrate.

Example 9 provides a method including forming a stiffener, for which the stiffener includes a frame with extension members that protrude from the frame, providing a device platform for forming a semiconductor package, for which the device platform includes a top surface and a bottom surface, disposing at least one semiconductor device onto the top surface of the device platform, and disposing the frame of the stiffener onto the top surface of the device platform, for which each of the extension members of the stiffener includes a bottom extension surface that is positioned proximal to a corner of the device platform and provide an extension to the bottom surface of the device platform.

Example 10 may include the method of example 9 and/or any other example disclosed herein, further including forming a solder ball grid array on the bottom extension surfaces and the bottom surface of the device platform, and disposing the bottom extension surfaces and the bottom surface of the device platform on a printed circuit broad.

Example 11 may include the method of example 10 and/or any other example disclosed herein, for which the solder ball grid array is attached to the printed circuit board using surface mounting technology.

Example 12 may include the method of example 10 and/or any other example disclosed herein, for which at least one row of solder balls is formed on the bottom extension surfaces.

Example 13 may include the method of example 9 and/or any other example disclosed herein, for which the forming of the frame and extension members of the stiffener includes providing a pre-shaped stiffener template and performing a heat-press process.

Example 14 may include the method of example 9 and/or any other example disclosed herein, for which the forming of the frame and extension members of the stiffener with extension members includes performing an injection molding process.

Example 15 provides a semiconductor package including a package substrate with a top surface and a bottom surface forming a periphery with corners, a rigid body with extension members, for which the rigid body is disposed on the top surface of the package substrate and extension members are positioned proximally to the corners of the package substrate, for which the extension members comprise bottom extension surfaces that extend beyond the periphery of the package substrate and a semiconductor device disposed on the top surface of the package substrate.

Example 16 may include the semiconductor package of example 15 and/or any other example disclosed herein, for which the bottom surface of the package substrate is co-planar with the bottom extension surfaces.

Example 17 may include the semiconductor package of example 15 and/or any other example disclosed herein, for which the rigid body of the stiffener includes a frame that is positioned along the periphery of the top surface of the package substrate.

Example 18 may include the semiconductor package of example 17 and/or any other example disclosed herein, for which the frame includes a unitary structure or an assembled structure.

Example 19 may include the semiconductor package of example 15 and/or any other example disclosed herein, for which the bottom extension surfaces have a width to accommodate at least one row of solder balls that are positioned beyond the periphery of the package substrate.

Example 20 may include the semiconductor package of example 15 and/or any other example disclosed herein, for which the rigid body includes aluminum, copper, steel, or another metal.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a body comprising extension members, wherein the body is a component of a semiconductor device package and the extension members are positioned for placement proximally at corners of a semiconductor package substrate; and
the extension members comprising bottom extension surfaces that extend beyond a periphery of a bottom surface of the semiconductor package substrate, wherein the bottom extension surfaces and the bottom surface of the semiconductor package substrate are co-planar.

2. The device of claim 1, wherein the body comprises a frame that is positioned along a periphery of an upper surface of the semiconductor package substrate.

3. The device of claim 2, wherein the frame comprises an assembled structure made from several subcomponents.

4. The device of claim 1, wherein the bottom extension surfaces have a width to accommodate at least one row of solder balls that are positioned beyond the periphery of the semiconductor package substrate.

5. The device of claim 1, wherein the body comprises a metallic material.

6. The device of claim 1, wherein the body comprises a ceramic material.

7. The device of claim 1, wherein the bottom extension surfaces are formed to be in close proximity with the bottom surface of the semiconductor package substrate.

8. The device of claim 1, wherein the bottom extension surfaces are formed to be spaced apart from the bottom surface of the semiconductor package substrate.

9. A method comprising:
forming a stiffener, wherein the stiffener comprises a frame with extension members that protrude from the frame;
providing a device platform for forming a semiconductor package, wherein the device platform comprises a top surface and a bottom surface;
disposing at least one semiconductor device onto the top surface of the device platform; and
disposing the frame of the stiffener onto the top surface of the device platform, wherein each of the extension members of the stiffener comprises a bottom extension surface that is positioned proximal to a corner of the device platform and provides an extension to the bottom surface of the device platform.

10. The method of claim 9, further comprising forming a solder ball grid array on the bottom extension surfaces and the bottom surface of the device platform; and
disposing the bottom extension surfaces and the bottom surface of the device platform on a printed circuit broad.

11. The method of claim 10, wherein the solder ball grid array is attached to the printed circuit board using surface mounting technology.

12. The method of claim 10, wherein at least one row of solder balls is formed on the bottom extension surfaces.

13. The method of claim 9, wherein the forming of the frame and extension members of the stiffener comprises providing a pre-shaped stiffener template and performing a heat-press process.

14. The method of claim 9, wherein the forming of the frame and extension members of the stiffener with extension members comprises performing an injection molding process.

15. A semiconductor package comprising:
a package substrate comprising a top surface and a bottom surface forming a periphery with corners;
a rigid body with extension members, wherein the rigid body is disposed on the top surface of the package substrate and extension members are positioned proximally to the corners of the package substrate;
wherein the extension members comprise bottom extension surfaces that extend beyond the periphery of the package substrate; and
a semiconductor device disposed on the top surface of the package substrate.

16. The semiconductor package of claim 15, wherein the bottom surface of the package substrate is co-planar with the bottom extension surfaces.

17. The semiconductor package of claim 15, wherein the rigid body comprises a frame that is positioned along the periphery of the top surface of the package substrate.

18. The semiconductor package of claim 17, wherein the frame comprises a unitary structure or an assembled structure.

19. The semiconductor package of claim 15, wherein the bottom extension surfaces have a width to accommodate at least one row of solder balls that are positioned beyond the periphery of the package substrate.

20. The semiconductor package of claim 15, wherein the rigid body comprises aluminum, copper, steel, or another metal.
